(19) United States
(12) Patent Application Publication
(10) Pub. No.: US 2008/0108503 A1
(43) Pub. Date: May 8, 2008

(54) INSPECTION APPARATUS

(75) Inventors: Takayuki Simizu, Morioka-shi (JP); Masahito Yoshizawa, Morioka-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: JAPAN SCIENCE AND TECHNOLOGY AGENCY, Kawaguchi-shi (JP)

(21) Appl. No.: 11/740,601

(22) Filed: Apr. 26, 2007

Related U.S. Application Data
(63) Continuation of application No. PCT/JP05/20039, filed on Oct. 31, 2005.

(30) Foreign Application Priority Data
Oct. 29, 2004 (JP) 2004-316942

(51) Int. Cl. G01R 33/035

(52) U.S. Cl. 505/162; 324/248

(57) ABSTRACT

An inspection apparatus capable of suppressing degradation of oxide superconductors comprises a transformer including a flux-change detection coil and a flux transmission coil and formed of a first superconductor, an SQUID element magnetically connected to the flux transmission coil and formed of a second superconductor, a first indirect cooling section containing the flux transmission coil and the SQUID element, a second indirect cooling section including a first through hole, the flux-change detection coil winding around the first through hole, a vessel including a second through hole formed therein and located inside the first through hole, the vessel making, a sealed space, a space in which the transformer and the SQUID element are located, and a cooling section thermally connected to the first and second indirect cooling sections to cool the transformer and the SQUID element to a value not higher than the critical temperatures of the first and second superconductors.

### CROSS-REFERENCE TO RELATED APPLICATIONS

This is a Continuation Application of PCT application No. PCT/JP2005/020039, filed Oct. 31, 2005, which was published under PCT Article 21(2) in Japanese.

This application is based upon and claims the benefit of priority from prior Japanese Patent Application No. 2004-316942, filed Oct. 29, 2004, the entire contents of which are incorporated herein by reference.

### BACKGROUND OF THE INVENTION

1. Field of the Invention

The present invention relates to an inspection apparatus for detecting micro metal particles, using an SQUID device.

2. Description of the Related Art

As a magnetism measurement device for detecting, for example, micro metal particles, a device acquired by applying a device employed in the basic research of physical properties that magnetic susceptibility can be pointed out (see non-patent document 1). It is very important in product safe control to detect micro metal particles that may be mixed in food, medicinal supplies and clothing and cause an unexpected accident.

In recent years, SQUID-device fluxmeters utilizing a superconducting quantum interference device (SQUID device), which can detect a magnetic flux of about 1/1,000,000,000 of the earth magnetism, are applied to various fields of research. These SQUID fluxmeters exhibit validity in the fields that require highly sensible noncontact magnetic measurement, and are also expected to exhibit high sensibility in the detection of micro metal particles.

It is contrived to use an oxide superconductor as the superconductor of SQUID devices. Oxide superconductors operate at relatively high temperature.

However, the critical temperatures of oxide superconductors are likely to vary in accordance with a change in composition. When the oxide superconductors frosted up in temperature-falling/temperature-rising cycle, oxygen will be removed to thereby change the composition and hence the critical temperatures.

Further, industrially, it is desirable that targets be inspected, carried by, for example, a belt conveyor.

Non-patent document 1: Physical Phenomenon and Application of Josephson Effect (Modern Scientific Corporation) pp. 412-414

### BRIEF SUMMARY OF THE INVENTION

It is an object of the invention to provide an inspection apparatus capable of suppressing degradation of the oxide superconductors of an SQUID device, and inspecting targets while carrying the targets by, for example, a belt conveyor.

An inspection apparatus according to an example of the invention is characterized by comprising: a transformer including a flux-change detection coil and a flux transmission coil and formed of a first superconductor; an SQUID element magnetically connected to the flux transmission coil and formed of a second superconductor; a first indirect cooling section containing the flux transmission coil and the SQUID element; a second indirect cooling section including a first through hole, the flux-change detection coil winding around the first through hole; a vessel including a second through hole formed therein and located inside the first through hole, the vessel making, a sealed space, a space in which the transformer and the SQUID element are located; and a cooling section formed of a nonmagnetic material and thermally connected to the first and second indirect cooling sections to cool the transformer and the SQUID element to a value not higher than critical temperatures of the first and second superconductors.

In the invention, a transformer and SQUID device are placed in a sealed-up space and indirectly cooled therein, instead of being soaked in liquid helium or liquid nitrogen, with the result that the devices are free from frost and degradation of the oxide superconductor of the devices is suppressed. Further, a belt conveyor can be located in a second through hole.

### BRIEF DESCRIPTION OF THE SEVERAL VIEWS OF THE DRAWING

FIG. 1 is a schematic view illustrating the structure of a measuring section and analysis section incorporated in a measurement apparatus according to an embodiment of the invention; and

FIG. 2 is a schematic view illustrating the structure of the measurement apparatus of the embodiment.

### DETAILED DESCRIPTION OF THE INVENTION

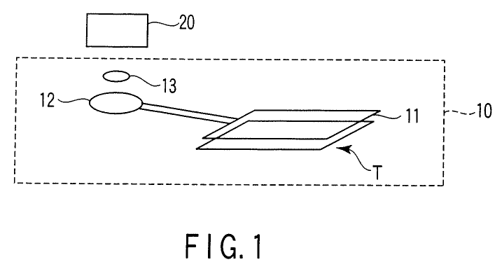

FIG. 1 is a schematic view illustrating the structure of a measuring section and analysis section incorporated in an inspection apparatus according to an embodiment of the invention.

As shown in FIG. 1, a measuring section 10 comprises a transformer T including a flux-change detection coil 11 and flux transmission coil 12, and an SQUID device 13 adjacent to the flux transmission coil 13 and magnetically coupled thereto. The flux-change detection coil 11 and flux transmission coil 12 are formed of a tape member that contains, as a base material, a so-called high-temperature superconductor having a critical temperature T_{c} not higher than the boiling point of liquid nitrogen. In the embodiment, the tape member used is produced by a powder-in-tube method, using, as a base material, (Bi,Pb)₂Sr₂Ca₂Cu₃Oₓ (first oxide superconductor) having a critical temperature T_{c} of 110K, and using silver for a sheath member.

Further, the SQUID device 13 is formed of a substrate, and a Bi-based superconducting thin film (second oxide superconductor) provided on the substrate.

The flux-change detection coil 11 is a primary differential type coil of 600 mm×250 mm. Further, since the flux transmission coil 12 supplies a signal to the SQUID device 13, it is desirable that the flux transmission coil 12 should perform flux condensation. To perform flux condensation, it is necessary to set the line density of the coil high. As mentioned above, the oxide superconducting tape member is produced by the “powder-in-tube method”. In this case, it is most effective to suppress an increase in the radial thickness of the coil due to an increase in the number of windings of the coil. To this end, it is preferable to employ a straight-angle coil wound in an α-shape. The flux transmission coil 12 of the embodiment is an α-shaped coil with a diameter of 20 mm and 50 windings. To perform flux condensation, a magnetic core may be provided at the center of the flux transmission coil 12.

When a change occurs in the magnetic flux of the flux-change detection coil 11, a shielding current for offsetting the flux change flows through the superconductor. The shielding current flows into the flux transmission coil. The flux transmission coil, in turn, converts the shielding current into magnetism and amplifies it. The SQUID device 13 detects the magnetism generated in the flux transmission coil. Thus, the SQUID device 13 detects and measures a change in the magnetic flux of the flux-change detection coil 11.

Since an analysis section 20 for analyzing a signal detected by the SQUID device 13 is similar to known magnetic susceptibility measuring devices, it is not described in detail. The SQUID device 13 can couple a high-order differential type gradiometer, such as a primary differential gradiometer, to a vector type magnetometer.

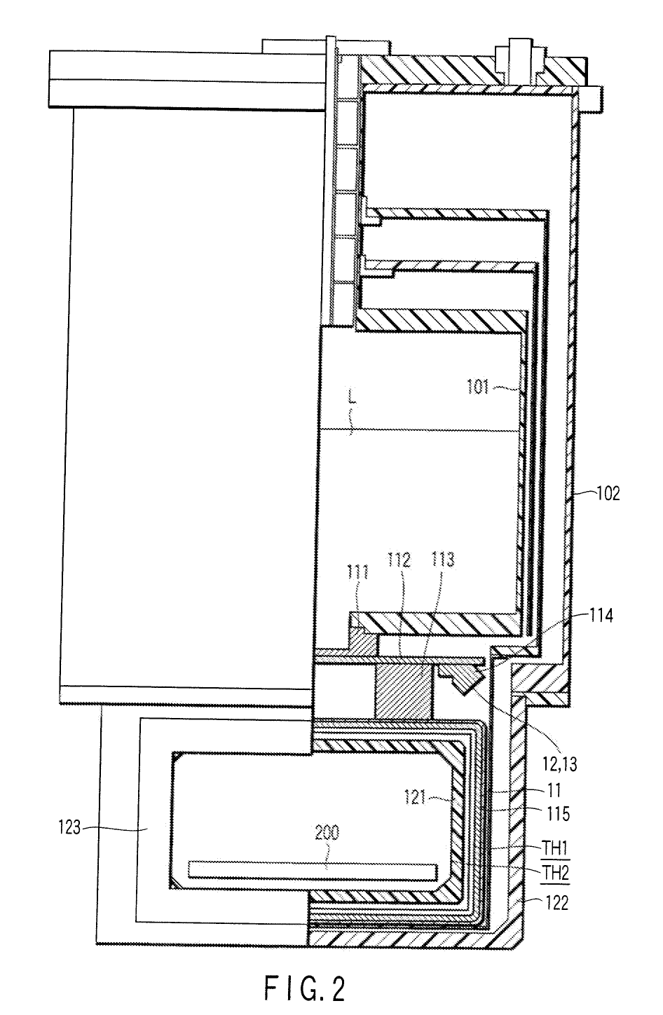

The measuring section 10 shown in FIG. 1 is contained in a Dewar vessel as shown in FIG. 2. FIG. 2 is a schematic view illustrating a Dewar vessel according to the embodiment of the invention.

As shown in FIG. 2, liquid helium L is contained in an internal vessel (cooling section) 101. The bottom of the internal vessel 101 includes a first Cu member 111. A second Cu member 112 is provided on the lower surface of the first Cu member 111. A third Cu member 113, and a fourth Cu member 114, which defines a first indirect cooling section, are provided on the lower surface of the second Cu member 112. The fourth Cu member 114 is thermally connected to the liquid helium contained in the internal vessel 101 via the first and second Cu members 111 and 112. A fifth Cu member 115, which defines a second indirect cooling section and has a first through hole, is connected to the lower surface of the third Cu member 113. The fifth Cu member 115 is thermally connected to the liquid helium contained in the internal vessel 101 via the first, second and third Cu members 111, 112 and 113.

The flux-change detection coil 11 is provided on the fifth Cu member 115 so that it winds around the first through hole TH1. The flux-change detection coil 11 is cooled to a value not higher than its superconducting critical temperature by the fifth Cu member 115 thermally connected to the liquid helium contained in the internal vessel 101.

The flux transmission coil 12 and the SQUID device 13 magnetically connected thereto are provided on the fourth Cu member 114. The flux transmission coil 12 and SQUID device 13 are cooled to a value not higher than their superconducting critical temperatures by the fourth Cu member 114 thermally connected to the liquid helium contained in the internal vessel 101.

A first fiber-reinforced plastic (FRP) member 121 having a second through hole TH2 is provided in the first through hole TH1. An external vessel 102 is provided outside the internal vessel 101. A second fiber-reinforced plastic (FRP) member 122 is provided to define the bottom of the external vessel 102.

A third fiber-reinforced plastic (FRP) member 123 is provided to seal the space defined by the internal vessel 101, external vessel 102, first FRP member 121 and second FRP member 122. The sealed space contains the transformer T and SQUID device 13.

A belt conveyor 200 can be provided in the second through hole TH2. While the belt conveyor 200 is being operated, inspection targets are passed in the through hole TH2 along with the conveyor, to inspect whether they contain metal particles.

In the embodiment, the internal vessel 101 for cooling the transformer T and SQUID device 13 is formed not of metal, but of nonmagnetic fiber-reinforced plastic (FRP). Accordingly, degradation of the SQUID device 13 can be prevented. Further, at the temperature of liquid helium, adhesives are likely to crack and peel off, and therefore cannot be used for construction materials. However, since in the invention, the internal and external vessels 102 and 101 are formed integral, liquid helium can be contained in the internal vessel 102.

In a temperature decreasing/increasing process in which after the measuring section formed of the transformer and SQUID element is soaked in and cooled by liquid nitrogen or helium, it is returned to the room temperature, frost occurs on the transformer T and SQUID element 13. Oxide superconductors are likely to degrade when they touch moisture due to condensation.

In the apparatus of the embodiment, to cool the transformer T and SQUID element 13, the internal vessel 102 containing liquid helium is thermally connected to the transformer T and SQUID element 13 using the first Cu member 111, external vessel 101 and second Cu member 112. Further, the transformer T and SQUID element 13 are placed in a vacuum space. This being so, even through the temperature decreasing/increasing process, frost does not occur on the transformer T or SQUID element 13. Note that a dried inert gas may be contained in the sealed space, instead of causing the space to have a vacuum state.

Furthermore, MgB₂, which is also a superconductor that easily degrades, may be used as the material of the transformer T and SQUID element.

The invention is not limited to the above-described embodiment. For instance, although in the embodiment, liquid helium is contained in the internal vessel of the Dewar vessel, liquid nitrogen may be contained in the internal vessel if the transformer T and SQUID element 13 are cooled to a value not higher than the critical temperatures. A Bi-based material is used as an oxide superconductor forming the transformer T and SQUID element 13. However, another oxide superconductor may be used. An oxide superconductor, whose critical temperature is less than the boiling point of liquid nitrogen, may be used. Although in the embodiment, a Dewar vessel containing liquid helium is used as a cooling section for cooling the transformer T and SQUID element 13, a refrigerator with no coolant (e.g., a GM type, pulse tube type, starring type) may be employed.

In addition to the above, the invention may be modified in various ways without departing from the scope.

What is claimed is:

1. An inspection apparatus characterized by comprising:
a transformer including a flux-change detection coil and a flux transmission coil and formed of a first superconductor;
an SQUID element magnetically connected to the flux transmission coil and formed of a second superconductor;
a first indirect cooling section containing the flux transmission coil and the SQUID element;
a second indirect cooling section including a first through hole, the flux-change detection coil winding around the first through hole;
a vessel including a second through hole formed therein and located inside the first through hole, the vessel making, a sealed space, a space in which the transformer and the SQUID element are located; and
a cooling section thermally connected to the first and second indirect cooling sections to cool the transformer and the SQUID element to a value not higher than critical temperatures of the first and second superconductors.

2. The inspection apparatus according to claim 1, characterized in that the sealed space is a vacuum space.

3. The inspection apparatus according to claim 1, characterized in that a magnetic core is provided at substantially a center of the flux transmission coil.

4. The inspection apparatus according to claim 1, characterized in that the critical temperatures of the first and second superconductors are not lower than a boiling point of liquid nitrogen.

5. The inspection apparatus according to claim 1, characterized in that the first superconductor is a tape-form or a wire-form containing an oxide superconductor as a base material.

6. The inspection apparatus according to claim 1, characterized in that the first and second superconductors are made from MgB₂.

7. The inspection apparatus according to claim 1, characterized in that the cooling section is constructed by fiber-reinforced plastic (FRP).

8. The inspection apparatus according to claim 1, characterized by further comprising a belt conveyor used to pass a to-be-inspected object through the second through hole.
